(19) United States
(12) Patent Application Publication
(10) Pub. No.: US 2026/0068330 A1
(43) Pub. Date: Mar. 5, 2026

(54) SEMICONDUCTOR DEVICE

(71) Applicant: Renesas Electronics Corporation, Tokyo (JP)

(72) Inventor: Koki NARITA, Tokyo (JP)

(21) Appl. No.: 19/262,254

(22) Filed: Jul. 8, 2025

(30) Foreign Application Priority Data
Sep. 2, 2024 (JP) 2024-150736

(51) Int. Cl. H10D 89/60

(52) U.S. Cl. CPC H10D 89/819

(57) ABSTRACT

A semiconductor device includes a protection transistor connected between a power supply and GND, a trigger circuit configured to detect an application of ESD and output a drive signal to a gate of the protection transistor, and a switch provided between the power supply or the GND and the gate of the protection transistor and configured to electrically connect the power supply or the GND and the gate of the protection transistor when the ESD is applied to the GND.

### CROSS-REFERENCE TO RELATED APPLICATIONS

The disclosure of Japanese Patent Application No. 2024-150736 filed on Sep. 2, 2024 including the specification, drawings and abstract is incorporated herein by reference in its entirety.

### BACKGROUND

The present invention relates to a semiconductor device, for example, a semiconductor device having a protection function against an electrostatic discharge (ESD).

An electrostatic protection circuit configured to protect an internal circuit from an electrostatic discharge from outside is mounted in a semiconductor device.

There is disclosed a technique listed below.
[Patent Document 1] U.S. Pat. No. 5,946,177

As an electrostatic protection circuit of this kind, a circuit made up of, for example, an RC timer, an inverter, and a protection transistor configured to have a large size in order to discharge an applied ESD can be presented (see, for example, Patent Document 1).

### SUMMARY

The circuit made up of an RC timer and an inverter described above operates when an electrostatic discharge is applied to a power supply line, but does not operate when an electrostatic discharge is applied to a reference potential line such as GND or Vss.

When an electrostatic discharge is applied to a reference potential line, a current is discharged mainly through a body diode formed between a drain of a protection transistor and a guard ring. However, in the case of the silicon on insulator (SOI) process, the body diode is not formed because source, drain, and channel of the transistor are separated from an Si substrate by a buried oxide (BOX) layer. Therefore, a stress voltage between a power supply line and a reference potential line increases, resulting in the increase of a risk of element destruction due to electrostatic discharge.

There is also an option to add a diode between a power supply line and a reference potential line, but it causes the increase of chip area because it is necessary to increase the size of the diode to be added.

The embodiments to be described below have been made in consideration of the above circumstances, and other problems and novel features will be apparent from the description of this specification and accompanying drawings.

A semiconductor device according to one embodiment includes a protection transistor connected between a power supply line and a reference potential line, a trigger circuit configured to detect an application of an electrostatic discharge to the power supply line and output a drive signal to a gate of the protection transistor, and a switching circuit provided between the power supply line or the reference potential line and the gate of the protection transistor and configured to electrically connect the power supply line or the reference potential line and the gate of the protection transistor when the electrostatic discharge is applied to the reference potential line.

According to the above embodiment, it is possible to improve the performance of an electrostatic protection circuit.

### BRIEF DESCRIPTION OF THE DRAWINGS

FIG. 1 is a schematic circuit example of a semiconductor device according to the first embodiment.

FIG. 2 is a diagram illustrating an operation in the semiconductor device in FIG. 1.

FIG. 3 is a diagram illustrating an operation in the semiconductor device in FIG. 1.

FIG. 4 is a diagram illustrating an operation in the semiconductor device in FIG. 1.

FIG. 5 is a detailed circuit example in the semiconductor device in FIG. 1.

FIG. 6 is a modification of the semiconductor device in FIG. 1.

FIG. 7 is a circuit example of a semiconductor device according to the second embodiment.

FIG. 8 is a modification of the semiconductor device in FIG. 7.

FIG. 9 is a circuit example of a semiconductor device according to the third embodiment.

FIG. 10 is a diagram illustrating an operation in the semiconductor device in FIG. 9.

FIG. 11 is a modification of the semiconductor device in FIG. 9.

FIG. 12 is a diagram illustrating an operation in the semiconductor device in FIG. 11.

FIG. 13 is a circuit example of a semiconductor device according to the fourth embodiment.

FIG. 14 is a diagram illustrating an operation in the semiconductor device in FIG. 13.

FIG. 15 is a diagram illustrating an operation in the semiconductor device in FIG. 13.

### DETAILED DESCRIPTION

embodiments, when necessary for In the following convenience, the invention will be described in a plurality of sections or embodiments, but the sections or embodiments are not irrelevant to each other unless otherwise specified, and one is in a relationship of modification, details, supplementary description, and the like of a part or all of the other. In addition, in the following embodiments, when referring to the number of elements and the like (including number, numerical value, amount, range, and the like), the number is not limited to a specific number unless otherwise specified or clearly limited to the specific number in principle, and the number may be equal to or more than or less than the specific number.

Furthermore, in the following embodiments, it goes without saying that the components (including element steps and the like) are not necessarily essential unless otherwise specified or considered to be obviously essential in principle. Similarly, in the following embodiments, when referring to the shape, positional relationship, and the like of the components and the like, it is assumed to include those substantially approximate or similar to the shape and the like unless otherwise specified or unless clearly considered otherwise in principle. The same applies to the above numerical value and range.

Also, circuit elements constituting each functional block of the embodiments are not particularly limited, but are formed on a semiconductor substrate such as a single crystal silicon substrate by a publicly known integrated circuit technology for complementary MOS transistors (CMOS) or the like. In the embodiments, metal oxide semiconductor field effect transistors (MOSFETs abbreviated as MOS transistors) are used as an example of metal insulator semiconductor field effect transistors (MISFETs), but this does not exclude the use of non-oxide films as gate insulating films. Further, in the embodiments, p channel MOSFETs and n channel MOSFETs are referred to as pMOS transistors and nMOS transistors, respectively.

Hereinafter, embodiments of the present invention will be described in detail with reference to the drawings. Note that, in all the drawings for describing the embodiments, the same members are denoted by the same reference characters in principle, and repetitive description thereof will be omitted.

### First Embodiment

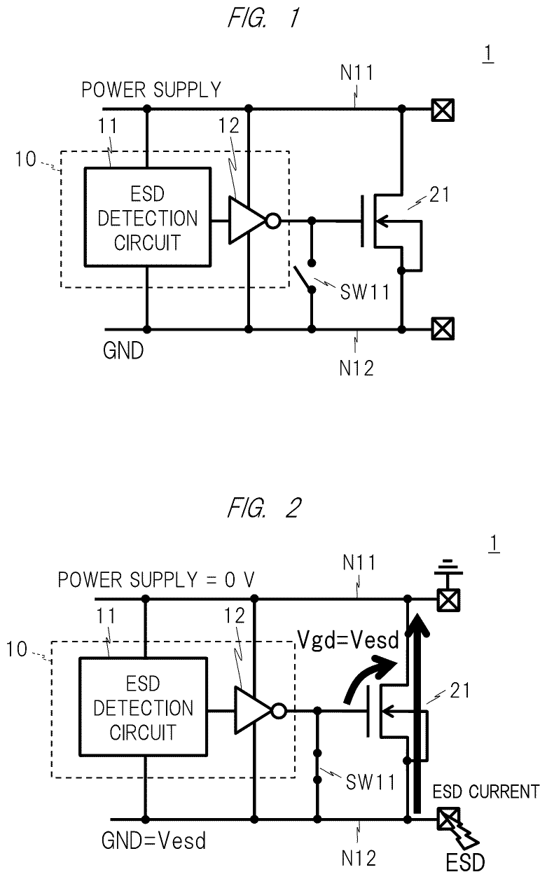

FIG. 1 illustrates a schematic diagram of a semiconductor device according to this embodiment. FIG. 1 is a schematic circuit example of an electrostatic protection circuit portion of a semiconductor device 1 according to this embodiment. The semiconductor device 1 includes a trigger circuit 10, a protection transistor 21, and a switch SW11.

The trigger circuit 10 includes an ESD detection circuit 11 and an inverter 12. The ESD detection circuit 11 detects an application of an electrostatic discharge (hereinafter referred to as ESD) to a power supply line, and outputs a detection signal to the inverter 12. The inverter 12 outputs a drive signal to a gate of the protection transistor 21 based on the detection signal. Also, the ESD detection circuit 11 and the inverter 12 are connected between a power supply node N11 (power supply line) and a power supply node N12 (GND: reference potential line). Here, the power supply node N11 is a node at which a power supply voltage on a high potential side is applied to the ESD detection circuit 11 and the inverter 12, and the power supply node N12 is a node at which a power supply voltage on a low potential side is applied to the ESD detection circuit 11 and the inverter 12.

Note that the power supply line (power supply node N11) illustrated in FIG. 1 is a node at which a power supply voltage (for example, Vdd) having a higher potential than that of the GND in FIG. 1 is supplied. The GND (power supply node N12) is a node at which a power supply voltage (referred to also as reference potential) having a lower potential than that of the power supply line is supplied.

The protection transistor 21 is made up of an nMOS transistor and is connected between the power supply node N11 and the power supply node N12. Specifically, a drain of the protection transistor 21 is connected to the power supply node N11, and a source of the protection transistor 21 is connected to the power supply node N12. When ESD is applied to the power supply line or GND, the protection transistor 21 turns on and discharges the current caused by the application of ESD.

The switch SW11 is provided between the power supply node N12 and the gate of the protection transistor 21. The switch SW11 electrically connects or disconnects the power supply node N12 and the gate of the protection transistor 21. The switch SW11 can be made up of, for example, a transistor as illustrated in FIG. 5. The switch SW11 is controlled to be switched on or off by, for example, the potential of the power supply node N11 as illustrated in FIG. 5.

Namely, in the configuration illustrated in FIG. 1, the ESD detection circuit 11 corresponds to a detection circuit, the inverter 12 corresponds to a drive circuit, and the switch SW11 corresponds to a switching circuit.

### Operation in this Embodiment

Next, the operation of the electrostatic protection circuit in the semiconductor device 1 configured as described above will be described with reference to FIG. 2 to FIG. 4.

FIG. 2 is a diagram illustrating a case where ESD is applied to the GND (power supply node N12: reference potential line). At this time, a voltage Vesd is applied to the GND (power supply node N12). On the other hand, the power supply line (power supply node N11) is at 0 V. In this case, the ESD detection circuit 11 cannot detect the application of ESD.

Then, the switch SW11 is turned on. Consequently, the power supply node N12 (GND) and the gate of the protection transistor 21 are electrically connected (short-circuited), so that the potential of the gate of the protection transistor 21 rises to the same level as that of the power supply node N12 (GND). Therefore, a gate-drain voltage Vgd of the protection transistor 21 increases to Vesd, and the protection transistor 21 is driven at a voltage sufficient to allow a current caused by the application of ESD (ESD current) to flow. Therefore, even if a body diode is not formed, sufficient clamping performance can be maintained. In other words, when ESD is applied to the GND (reference potential line), the switch SW11 electrically connects the GND (reference potential line) and the gate of the protection transistor 21.

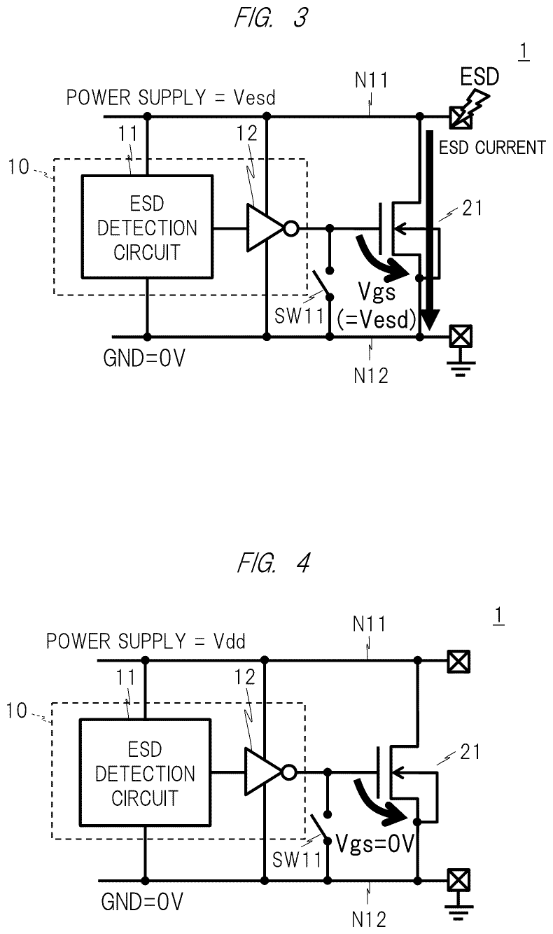

FIG. 3 is a diagram illustrating a case where ESD is applied to the power supply line (power supply node N11). At this time, a voltage Vesd is applied to the power supply line (power supply node N11). On the other hand, GND (power supply node N12) is at 0 V. In this case, the ESD detection circuit 11 outputs a Lo level indicating the application of ESD, and the inverter 12 outputs a Hi level. Therefore, the protection transistor 21 is turned on, that is, the gate-source voltage Vgs of the protection transistor 21 becomes Vesd, and the current caused by the application of ESD is discharged.

In the case of FIG. 3, the switch SW11 is off. Therefore, it is possible to prevent the switch SW11 from interfering with the output signal of the trigger circuit 10 (inverter 12) when ESD is applied to the power supply line (power supply node N11).

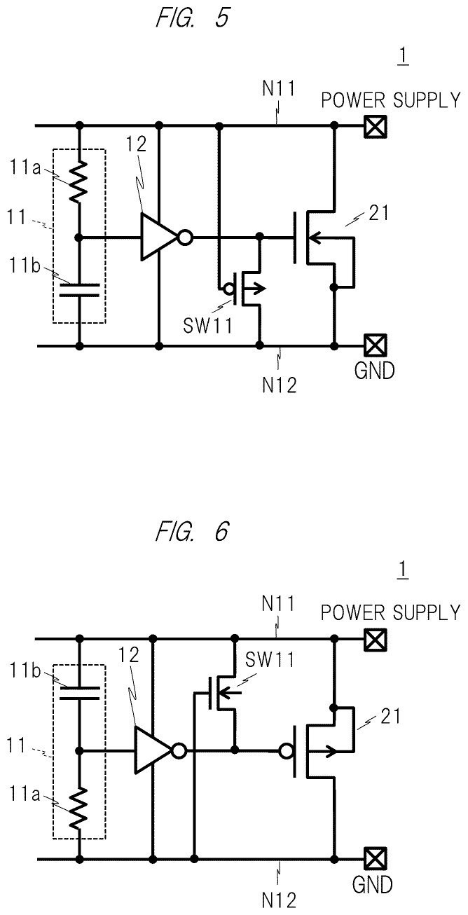

FIG. 4 is a diagram illustrating the state when turning the power on (when ESD is not applied). At this time, a voltage Vdd is applied to the power supply line (power supply node N11). On the other hand, the GND (power supply node N12) is at 0 V. In this case, the ESD detection circuit 11 outputs a Hi level, and the inverter 12 outputs a Lo level. Therefore, the protection transistor 21 is in an off state, that is, the gate-source voltage Vgs of the protection transistor 21 becomes 0 V, and no current is discharged.

In the case of FIG. 4, the switch SW11 is off. Therefore, it is possible to prevent the switch SW11 from interfering with the output signal of the trigger circuit 10 (inverter 12) when turning the power on (when ESD is not applied).

### Detailed Circuit in this Embodiment

Next, a detailed circuit example of the configuration illustrated in FIG. 1 will be described. In the detailed circuit illustrated in FIG. 5, the ESD detection circuit 11 is made up of a resistive element 11a and a capacitive element 11b. The resistive element 11a and the capacitive element 11b are connected in series between the power supply node N11 and the power supply node N12. Namely, one end of the resistive element 11a is connected to the power supply node N11, and the other end thereof is connected to one end of the capacitive element 11b. The other end of the capacitive element 11b is connected to the power supply node N12. Further, a connection point between the resistive element 11a and the capacitive element 11b is connected to an input of the inverter 12. The ESD detection circuit 11 is a well-known RC timer, and a time constant that reacts only in the case of a high slew rate such as the application of ESD is set.

The switch SW11 is made up of a pMOS transistor. A source of the switch SW11 is connected to the gate of the protection transistor 21, and a drain thereof is connected to the power supply node N12. Also, the power supply node N11 is connected to a gate of the switch SW11. When ESD is applied to the GND (power supply node N12) and the potential rises, the drain-gate voltage Vdg of the pMOS transistor constituting the switch SW11 increases and the switch SW11 is turned on. In other words, the switch SW11 is turned on when ESD is applied to the GND. When the switch SW11 is turned on, it electrically connects the power supply node N12 and the gate of the protection transistor 21 as described above. Namely, the switch SW11 electrically connects the reference potential line and the gate of the protection transistor 21 based on the potential of the power supply line.

On the other hand, the switch SW11 is turned off when ESD is not applied to the GND. When the switch SW11 is turned off, it electrically disconnects the power supply node N12 and the gate of the protection transistor 21.

Also, when ESD is applied to the power supply line (power supply node N11), the trigger circuit 10 operates and the inverter 12 outputs a Hi level. At this time, since the gate and source of the pMOS transistor constituting the switch SW11 have the same potential and the switch SW11 is turned off, the switch SW11 does not affect the output signal of the inverter 12.

Further, when turning the power on, the inverter 12 outputs a Lo level (0 V). At this time, the source and drain of the pMOS transistor constituting the switch SW11 are at 0 V, the gate thereof becomes Vdd, and the switch SW11 is turned off.

### Modification

Next, a modification of this embodiment will be described. FIG. 6 is a circuit example in a case where the protection transistor 21 is made up of a pMOS transistor. In the circuit of FIG. 6, the configuration of the ESD detection circuit 11 and the configuration of the switch SW11 are different from those of FIG. 5.

In the ESD detection 11, circuit the connection relationship between the capacitive element 11b and the resistive element 11a is reversed from that of FIG. 5. Specifically, one end of the capacitive element 11b is connected to the power supply node N11, and the other end thereof is connected to one end of the resistive element 11a. The other end of the resistive element 11a is connected to the power supply node N12. Further, a connection point between the capacitive element 11b and the resistive element 11a is connected to the input of the inverter 12.

The switch SW11 is made up of an nMOS transistor. A drain of the switch SW11 is connected to the power supply node N11, and a source thereof is connected to the gate of the protection transistor 21. Namely, the switch SW11 is connected between the power supply line and the gate of the protection transistor 21. Also, the power supply node N12 is connected to a gate of the switch SW11.

When ESD is applied to the GND (power supply node N12) and the potential rises, the gate-drain voltage Vgd of the nMOS transistor constituting the switch SW11 increases and the switch SW11 is turned on. When the switch SW11 is turned on, it electrically connects the power supply node N11 and the gate of the protection transistor 21. Then, the power supply line (power supply node N11) and the gate of the protection transistor 21 which is a pMOS transistor are connected, and the drain-gate voltage Vdg of the protection transistor 21 increases and the protection transistor 21 is driven at a voltage sufficient to allow the ESD current to flow. Namely, the switch SW11 electrically connects the power supply line and the gate of the protection transistor 21 when ESD is applied to the GND (reference potential line). Also, the switch SW11 electrically connects the power supply line and the gate of the protection transistor 21 based on the potential of the reference potential line.

On the other hand, the switch SW11 is turned off when ESD is not applied to the GND. When the switch SW11 is turned off, it electrically disconnects the power supply node N11 and the gate of the protection transistor 21.

Also, when ESD is applied to the power supply line (power supply node N11), the trigger circuit 10 operates and the inverter 12 outputs a Lo level. At this time, since the gate and source of the nMOS transistor constituting the switch SW11 have the same potential and the switch SW11 is turned off, the switch SW11 does not affect the output signal of the inverter 12.

Further, when turning the power on, the inverter 12 outputs a Hi level (Vdd). At this time, the source and drain of the nMOS transistor constituting the switch SW11 are at Vdd, the gate thereof becomes 0 V, and the switch SW11 is turned off.

In the semiconductor device 1 with the above configuration, it is possible to electrically connect the power supply line (when the protection transistor 21 is a pMOS transistor) or the reference potential line (when the protection transistor 21 is an nMOS transistor) and the gate of the protection transistor 21 by the switch SW11. Accordingly, this only requires the addition of a small-sized switch, and the increase in chip area can be kept to a minimum as compared with the addition of a large-sized protection diode. Therefore, the clamping performance against the application of ESD from the GND to the power supply can be improved. This is particularly effective for semiconductor devices manufactured by a process in which a body diode is not formed such as an SOI process.

### Second Embodiment

Next, the second embodiment will be described. In the following, the description of the parts overlapping with the above-mentioned embodiment will be omitted in principle.

### Circuit Configuration in this Embodiment

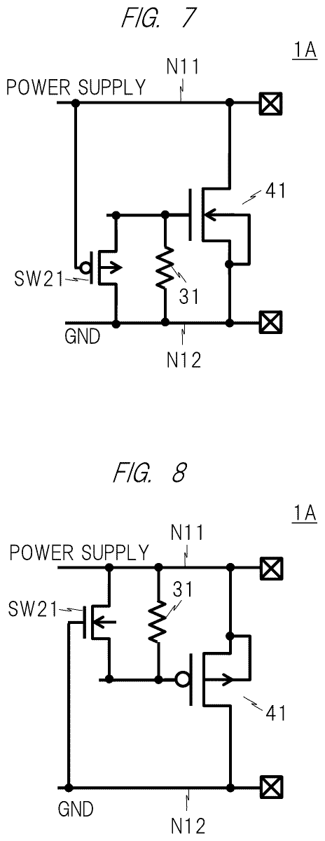

FIG. 7 illustrates a schematic diagram of a semiconductor device according to this embodiment. FIG. 7 is a circuit example of an electrostatic protection circuit portion of a semiconductor device 1A according to this embodiment. The semiconductor device 1A includes a resistive element 31, a protection transistor 41, and a switch SW21. The circuit illustrated in this embodiment is, for example, an electrostatic protection circuit for a circuit to which an internal power supply is supplied. The internal power supply is, for example, a power supply obtained by stepping down a primary power supply supplied from the outside by an internal power supply circuit such as a power supply IP.

The protection transistor 41 is made up of an nMOS transistor and is connected between the power supply node N11 (power supply line) and the power supply node N12 (GND). Namely, a drain of the protection transistor 41 is connected to the power supply node N11, and a source of the protection transistor 41 is connected to the power supply node N12. When ESD is applied to the power supply line or GND, the protection transistor 41 turns on and discharges the current caused by the application of ESD.

One end of the resistive element 31 is connected to a gate of the protection transistor 41 and the other end thereof is connected to the GND (power supply node N12). The resistive element 31 functions as a trigger circuit in this embodiment together with the parasitic capacitance formed between the drain and gate of the protection transistor 41. In this embodiment, the internal power supply is supplied from the power supply IP or the like as described above. If the internal power supply rises quickly, the trigger circuit illustrated in FIG. 5 or the like may react and cause a rush current to flow, so an RC circuit with a short time constant is formed by the resistive element 31 and the above parasitic capacitance instead of the trigger circuit with the configuration in FIG. 5 or the like.

The switch SW21 is made up of a pMOS transistor. A source of the switch SW21 is connected to the gate of the protection transistor 41, and a drain thereof is connected to the power supply node N12. Also, the power supply node N11 is connected to a gate of the switch SW21. When ESD is applied to the GND (power supply node N12) and the potential rises, the drain-gate voltage Vdg of the pMOS transistor constituting the switch SW21 increases and the switch SW21 is turned on. In other words, the switch SW21 is turned on when ESD is applied to the GND. When the switch SW21 is turned on, as described above, the switch SW21 electrically connects the power supply node N12 and the gate of the protection transistor 41.

When the switch SW21 is turned on, the gate-drain voltage Vgd of the protection transistor 41 increases to Vesd, and the protection diode 41 is driven at a voltage sufficient to allow the current caused by the application of ESD (ESD current) to flow. Therefore, even if a body diode is not formed, sufficient clamping performance can be maintained.

On the other hand, the switch SW21 is turned off when ESD is not applied to the GND (power supply node N12). When the switch SW21 is turned off, it electrically disconnects the power supply node N12 and the gate of the protection transistor 41.

### Modification

Next, a modification of this embodiment will be described. FIG. 8 is a circuit example in a case where the protection transistor 41 is made up of a pMOS transistor. In the circuit of FIG. 8, the connection of the resistive element 31 and the connection of the switch SW21 are different from those of FIG. 7.

One end of the resistive element 31 is connected to the power supply line (power supply node N11), and the other end thereof is connected to the gate of the protection transistor 41.

The switch SW21 is made up of an nMOS transistor. A drain of the switch SW21 is connected to the power supply node N11, and a source thereof is connected to the gate of the protection transistor 41. Also, the power supply node N12 is connected to a gate of the switch SW21. When ESD is applied to the GND (power supply node N12) and the potential rises, the gate-drain voltage Vgd of the nMOS transistor constituting the switch SW21 increases and the switch SW21 is turned on. When the switch SW21 is turned on, it electrically connects the power supply node N11 and the gate of the protection transistor 41. Then, the power supply line and the gate of the protection transistor 41 which is a pMOS transistor are connected, the drain-gate voltage Vdg of the protection transistor 41 increases, and the protection transistor 41 is driven at a voltage sufficient to allow the ESD current to flow.

On the other hand, the switch SW21 is turned off when ESD is not applied to the GND (power supply node N12). When the switch SW21 is turned off, it electrically disconnects the power supply node N11 and the gate of the protection transistor 41.

With the above configuration, the increase in chip area can be kept to a minimum even in the circuit using the internal power supply as in the semiconductor device 1A, and the clamping performance against the application of ESD from the GND to the power supply can be improved.

### Third Embodiment

Next, the third embodiment will be described. In the following, the description of the parts overlapping with the above-mentioned embodiments will be omitted in principle.

This embodiment is an application to a configuration in which protection transistors are stacked vertically. In recent years, the element withstand voltage has decreased along with the process miniaturization, but the voltage of the external interface has not decreased. Therefore, for electrostatic protection of a power supply to which a voltage higher than the element withstand voltage is supplied, the voltage applied to each protection transistor is reduced to below the element withstand voltage by the configuration in which the protection transistors are stacked vertically. In this embodiment, it is possible to improve the clamping performance against the application of ESD from the GND to the power supply even in such a configuration in which protection transistors are stacked vertically (connected in series).

### Circuit Configuration in this Embodiment

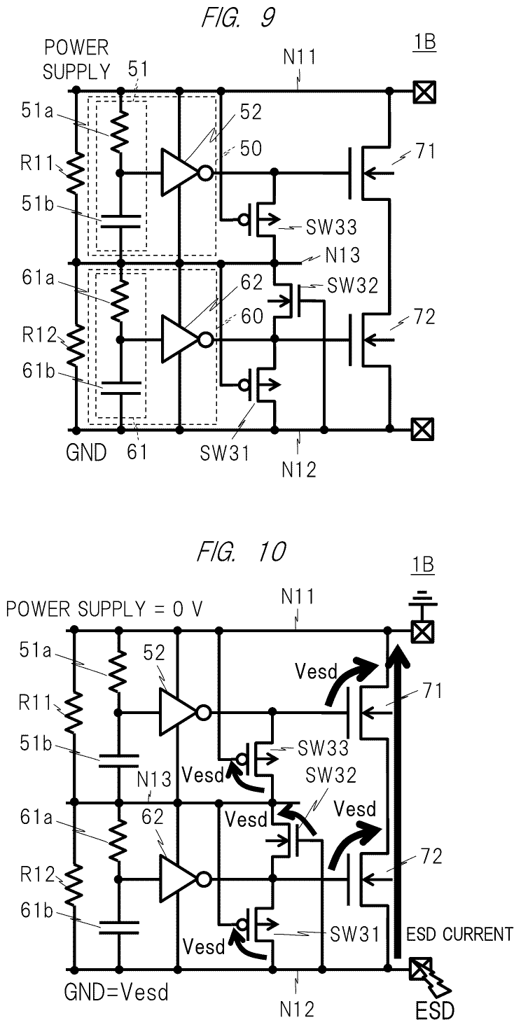

FIG. 9 illustrates a circuit example of an electrostatic protection circuit portion of a semiconductor device according to this embodiment. A semiconductor device 1B illustrated in FIG. 9 includes resistors R11 and R12, trigger circuits 50 and 60, protection transistors 71 and 72, and switches SW31, SW32, and SW33.

The resistors R11 and R12 are connected in series between the power supply line and the GND. The resistors R11 and R12 divide the voltage between the power supply line and the GND and supply it to a power supply node N13. In FIG. 9, the resistors R11 and R12 have the same resistance value, and a voltage obtained by dividing the power supply voltage by ½ is supplied to the power supply node N13, which is a connection point between the resistors R11 and R12. Note that the resistors R11 and R12 are not limited to resistive elements, and may be made up of transistors. Also, as long as a potential difference that allows an inverter 52 to operate normally can be secured, the voltage division ratio by the resistors R11 and R12 does not necessarily have to be ½ (1:1). Note that it is assumed that a voltage higher than the withstand voltage of each of the transistors constituting the protection transistors 71 and 72 and the switches SW31, SW32, and SW33 is applied to the power supply line in this embodiment.

The trigger circuit 50 includes an ESD detection circuit 51 and an inverter 52. The ESD detection circuit 51 detects the application of ESD to the power supply line (power supply node N11) and outputs a detection signal to the inverter 52. The inverter 52 outputs a drive signal to a gate of the protection transistor 71 based on the detection signal. Also, the ESD detection circuit 51 and the inverter 52 are connected between the power supply node N11 and the power supply node N13.

The ESD detection circuit 51 is made up of a resistive element 51a and a capacitive element 51b. The resistive element 51a and the capacitive element 51b are connected in series between the power supply node N11 and the power supply node N13. Namely, one end of the resistive element 51a is connected to the power supply node N11, and the other end thereof is connected to one end of the capacitive element 51b. The other end of the capacitive element 51b is connected to the power supply node N13. Further, a connection point between the resistive element 51a and the capacitive element 51b is connected to an input of the inverter 52.

The trigger circuit 60 includes an ESD detection circuit 61 and an inverter 62. The ESD detection circuit 61 detects the application of ESD to the power supply line (power supply node N11) and outputs a detection signal to the inverter 62. The inverter 62 outputs a drive signal to a gate of the protection transistor 72 based on the detection signal. Also, the ESD detection circuit 61 and the inverter 62 are connected between the power supply node N13 and the power supply node N12.

The ESD detection circuit 61 is made up of a resistive element 61a and a capacitive element 61b. The resistive element 61a and the capacitive element 61b are connected in series between the power supply node N13 and the power supply node N12. Namely, one end of the resistive element 61a is connected to the power supply node N13, and the other end thereof is connected to one end of the capacitive element 61b. The other end of the capacitive element 61b is connected to the power supply node N12. Further, a connection point between the resistive element 61a and the capacitive element 61b is connected to an input of the inverter 62.

The switch SW31 is made up of a pMOS transistor. A source of the switch SW31 is connected to the gate of the protection transistor 72, and a drain thereof is connected to the power supply node N12. Also, the power supply node N13 is connected to a gate of the switch SW31.

The switch SW32 is made up of an nMOS transistor. A drain of the switch SW32 is connected to the power supply node N13, and a source thereof is connected to the gate of the protection transistor 72. Also, the power supply node N12 is connected to a gate of the switch SW32.

The switch SW33 is made up of a pMOS transistor. A source of the switch SW33 is connected to the gate of the protection transistor 71, and a drain thereof is connected to the power supply node N13. Also, the power supply node N11 is connected to a gate of the switch SW33.

### Operation in this Embodiment

Next, the operation of the electrostatic protection circuit in the semiconductor device 1B configured as described above will be described with reference to FIG. 10. FIG. 10 is a diagram illustrating a case where ESD is applied to the GND (power supply node N12). Note that the frame lines indicating the trigger circuits 50 and 60 and the frame lines indicating the ESD detection circuits 51 and 61 are omitted in FIG. 10.

In the case of FIG. 10, a voltage Vesd is applied to the GND (power supply node N12). On the other hand, the power supply line (power supply node N11) is at 0 V. In this case, the ESD detection circuits 51 and 61 cannot detect the application of ESD. Here, when ESD is applied to the GND (power supply node N12) and the potential rises, the drain-gate voltage Vdg of the pMOS transistor constituting the switch SW31 increases (Vdg=Vesd) and the switch SW31 is turned on. In other words, the switch SW31 is turned on when ESD is applied to the GND. When the switch SW31 is turned on, it electrically connects the power supply node N12 and the gate of the protection transistor 72. On the other hand, the switch SW31 is turned off when ESD is not applied to the GND. When the switch SW31 is turned off, it electrically disconnects the power supply node N12 and the gate of the protection transistor 72.

When ESD is applied to the GND (power supply node N12) and the potential rises, the gate-drain voltage Vgd of the nMOS transistor constituting the switch SW32 increases (Vgd=Vesd) and the switch SW32 is turned on. In other words, the switch SW32 is turned on when ESD is applied to the GND. When the switch SW32 is turned on, it electrically connects the gate of the protection transistor 72 and the power supply node N13. On the other hand, the switch SW32 is turned off when ESD is not applied to the GND. When the switch SW32 is turned off, it electrically disconnects the gate of the protection transistor 72 and the power supply node N13.

When ESD is applied to the GND (power supply node N12) and the potential of the power supply line (power supply node N11) drops (0 V), the drain-gate voltage Vdg of the pMOS transistor constituting the switch SW33 increases (Vdg=Vesd) and the switch SW33 is turned on. In other words, the switch SW33 is turned on when ESD is applied to the GND. When the switch SW33 is turned on, it electrically connects the power supply node N13 and the gate of the protection transistor 71. On the other hand, the switch SW33 is turned off when ESD is not applied to the GND. When the switch SW33 is turned off, it electrically disconnects the power supply node N13 and the gate of the protection transistor 71.

Accordingly, the gate of the protection transistor 72 and the GND (power supply node N12) are electrically connected by turning on the switch SW31. Therefore, the gate-drain voltage Vgd of the protection transistor 72 increases to Vesd. Also, the gate of the protection transistor 71 and the GND are electrically connected by turning on the switches SW31, SW32, and SW33. Therefore, the gate-drain voltage Vgd of the protection transistor 71 increases to Vesd. Consequently, the protection transistors 71 and 72 are driven at a voltage sufficient to allow the current caused by the application of ESD (ESD current) to flow.

In other words, the switches SW31, SW32, and SW33 function as a plurality of switch elements that electrically connect the reference potential line and the gate of the protection transistor 71.

In addition, when applying ESD to the power supply line (power supply node N11) or when turning the power on, the switches SW31, SW32, and SW33 are all turned off, so the switches SW31, SW32, and SW33 do not affect the output signals of the inverters 52 and 62.

### Modification

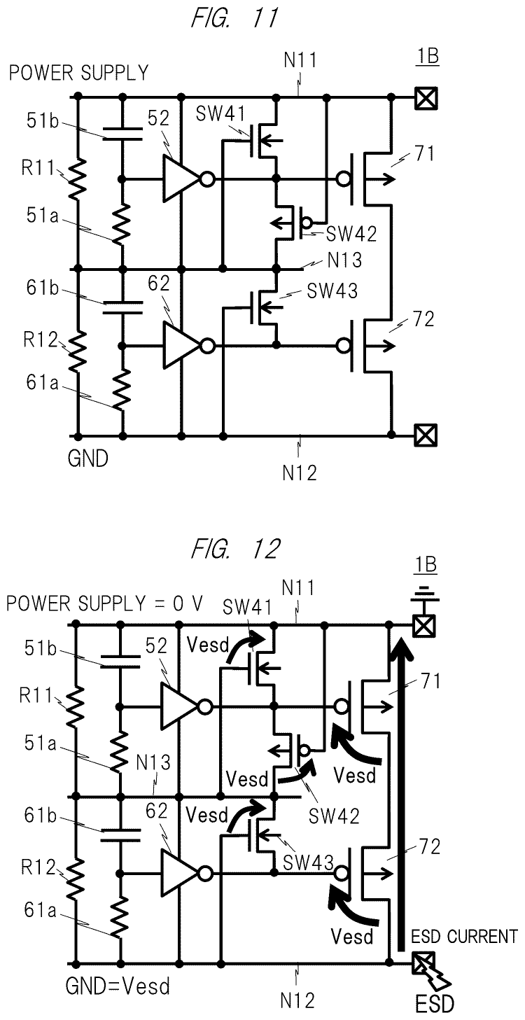

Next, a modification of this embodiment will be described. FIG. 11 is a circuit example in a case where the protection transistors 71 and 72 are made up of pMOS transistors. In the circuit of FIG. 11, the configurations of the ESD detection circuits 51 and 61 are different from those of FIG. 9. Also, switches SW41, SW42, and SW43 are provided instead of the switches SW31, SW32, and SW33.

In the ESD detection circuit 51, the connection relationship between the capacitive element 51b and the resistive element 51a is reversed from that of FIG. 9. Specifically, one end of the capacitive element 51b is connected to the power supply node N11, and the other end thereof is connected to one end of the resistive element 51a. The other end of the resistive element 51a is connected to the power supply node N13. Further, a connection point between the capacitive element 51b and the resistive element 51a is connected to the input of the inverter 52.

In the detection ESD circuit 61, the connection relationship between the capacitive element 61b and the resistive element 61a is reversed from that of FIG. 9. Specifically, one end of the capacitive element 61b is connected to the power supply node N13, and the other end thereof is connected to one end of the resistive element 61a. The other end of the resistive element 61a is connected to the power supply node N12. Further, a connection point between the capacitive element 61b and the resistive element 61a is connected to the input of the inverter 62.

The switch SW41 is made up of an nMOS transistor. A drain of the switch SW41 is connected to the power supply node N11, and a source thereof is connected to the gate of the protection transistor 71. Also, the power supply node N13 is connected to a gate of the switch SW41.

The switch SW42 is made up of a pMOS transistor. A source of the switch SW42 is connected to the gate of the protection transistor 71, and a drain thereof is connected to the power supply node N13. Also, the power supply node N11 is connected to a gate of the switch SW42.

The switch SW43 is made up of an nMOS transistor. A drain of the switch SW43 is connected to the power supply node N13, and a source thereof is connected to the gate of the protection transistor 72. Also, the power supply node N12 is connected to a gate of the switch SW43.

Next, the operation of the electrostatic protection circuit in this modification will be described with reference to FIG. 12. FIG. 12 is a diagram illustrating a case where ESD is applied to the GND.

In the case of FIG. 12, a voltage Vesd is applied to the GND (power supply node N12). On the other hand, the power supply line (power supply node N11) is at 0 V. In this case, the ESD detection circuits 51 and 61 cannot detect the application of ESD. Here, when ESD is applied to the GND (power supply node N12) and the potential of the power supply line (power supply node N11) drops (0 V), the gate-drain voltage Vgd of the nMOS transistor constituting the switch SW41 increases (Vdg=Vesd) and the switch SW41 is turned on. In other words, the switch SW41 is turned on when ESD is applied to the GND. When the switch SW41 is turned on, it electrically connects the power supply node N11 and the gate of the protection transistor 71. On the other hand, the switch SW41 is turned off when ESD is not applied to the GND. When the switch SW41 is turned off, it electrically disconnects the power supply node N11 and the gate of the protection transistor 71.

When ESD is applied to the GND (power supply node N12) and the potential of the power supply line (power supply node N11) drops (0 V), the drain-gate voltage Vdg of the pMOS transistor constituting the switch SW42 increases (Vdg=Vesd) and the switch SW42 is turned on. In other words, the switch SW42 is turned on when ESD is applied to the GND. When the switch SW42 is turned on, it electrically connects the gate of the protection transistor 71 and the power supply node N13. On the other hand, the switch SW42 is turned off when ESD is not applied to the GND. When the switch SW42 is turned off, it electrically disconnects the gate of the protection transistor 71 and the power supply node N13.

When ESD is applied to the GND (power supply node N12) and the potential rises, the gate-drain voltage Vgd of the nMOS transistor constituting the switch SW43 increases (Vdg=Vesd) and the switch SW43 is turned on. In other words, the switch SW43 is turned on when ESD is applied to the GND. When the switch SW43 is turned on, it electrically connects the power supply node N13 and the gate of the protection transistor 72. On the other hand, the switch SW43 is turned off when ESD is not applied to the GND. When the switch SW43 is turned off, it electrically disconnects the power supply node N13 and the gate of the protection transistor 72.

Accordingly, the gate of the protection transistor 71 and the power supply line (power supply node N11) are electrically connected by turning on the switch SW41. Therefore, the drain-gate voltage Vdg of the protection transistor 71 increases to Vesd. Also, the gate of the protection transistor 72 and the power supply line are electrically connected by turning on the switches SW41, SW42, and SW43. Therefore, the drain-gate voltage Vdg of the protection transistor 72 increases to Vesd. Consequently, the protection transistors 71 and 72 are driven at a voltage sufficient to allow the current caused by the application of ESD (ESD current) to flow.

In addition, when applying ESD to the power supply line (power supply node N11) or when turning the power on, the switches SW41, SW42, and SW43 are all turned off, so the switches SW41, SW42, and SW43 do not affect the output signals of the inverters 52 and 62.

With the above configuration, the increase in chip area can be kept to a minimum even in the circuit in which protection transistors are stacked vertically as in the semiconductor device 1B, and the clamping performance against the application of ESD from the GND to the power supply can be improved.

In addition, the case where the number of transistors to be stacked is 2 has been described in this embodiment, but it may be 3 or more. Even in the case where the number is 3 or more, the same effects can be obtained by providing MOS transistors serving as switches in the same manner as in the case where the number is 2.

### Fourth Embodiment

Next, the fourth embodiment will be described. In the following, the description of the parts overlapping with the above-mentioned embodiments will be omitted in principle.

This embodiment is an application to an output driver connected to an IO terminal of a semiconductor device.

FIG. 13 illustrates a circuit example of an output driver portion of a semiconductor device according to this embodiment. A semiconductor device 1C illustrated in FIG. 13 includes output transistors 81 and 82, a pre-driver 90, and switches SW51 and SW52.

The output transistor 81 is made up of a pMOS transistor. A source of the output transistor 81 is connected to the power supply node N11, and a drain thereof is connected to a node N14. Also, a gate of the output transistor 81 is connected to the pre-driver 90. In other words, the output transistor 81 is connected between an output terminal (IO terminal) and the power supply line (power supply node N11). Here, the node N14 is a node to which the IO terminal is connected.

The output transistor 82 is made up of an nMOS transistor. A drain of the output transistor 82 is connected to the node N14, and a source thereof is connected to the power supply node N12. Also, a gate of the output transistor 82 is connected to the pre-driver 90. In other words, the output transistor 82 is connected between the output terminal and the reference potential line (power supply node N12).

The pre-driver 90 drives the output transistor 81 and the output transistor 82 in accordance with a signal level output to the IO terminal.

The switch SW51 is made up of an nMOS transistor. A drain of the switch SW51 is connected to the power supply node N11, and a source thereof is connected to the gate of the output transistor 81. Also, a gate of the switch SW51 is connected to the node N14. In other words, the switch SW51 is provided between the power supply line (power supply node N11) and the gate of the output transistor 81.

The switch SW52 is made up of a pMOS transistor. A source of the switch SW52 is connected to the gate of the output transistor 82, and a drain thereof is connected to the power supply node N12. Also, a gate of the switch SW52 is connected to the node N14. In other words, the switch SW52 is provided between the reference potential line (power supply node N12) and the gate of the output transistor 82.

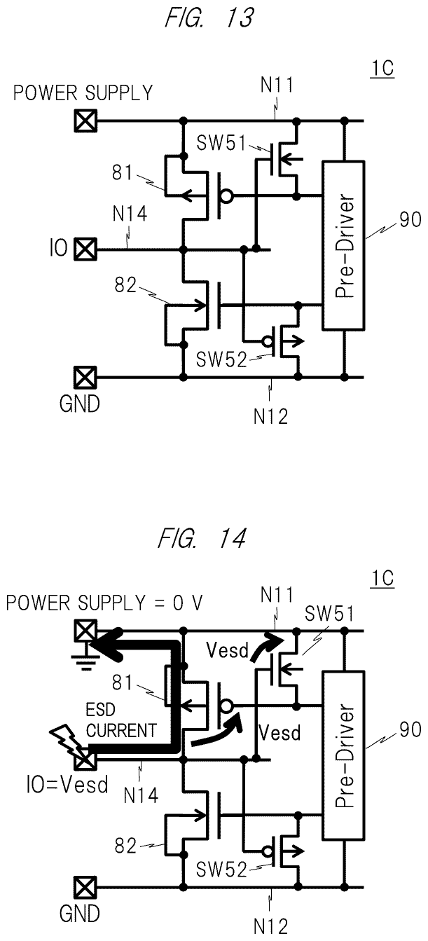

Next, the operation of the circuit illustrated in FIG. 13 will be described. FIG. 14 is a diagram illustrating a case where ESD is applied to the IO terminal. In the case of FIG. 14, a voltage Vesd is applied to the IO terminal (node N14). On the other hand, the power supply line (power supply node N11) is at 0 V. In this case, since the voltage Vesd is applied to the gate of the switch SW51, a gate-drain voltage Vgd of the nMOS transistor constituting the switch SW51 increases (to Vesd), and the switch SW51 is turned on. When the switch SW51 is turned on, the power supply node N11 and the gate of the output transistor 81 are electrically connected, a drain-gate voltage Vdg of the output transistor 81 increases, and the output transistor 81 is turned on.

Therefore, the output transistor 81 is driven at a voltage sufficient to allow the current caused by the application of ESD (ESD current) to flow.

Namely, the switch SW51 functions as a switching circuit configured to electrically connect the power supply node N11 (power supply line) and the gate of the output transistor 81 when the application of ESD to the IO terminal (output terminal) is detected.

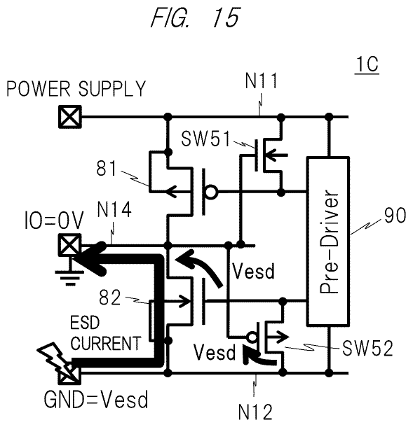

FIG. 15 is a diagram illustrating a case where ESD is applied to the GND. In the case of FIG. 15, a voltage Vesd is applied to the GND (power supply node N12). On the other hand, the IO terminal (node N14) is at 0 V. In this case, since 0 V is applied to the gate of the switch SW52, a drain-gate voltage Vdg of the pMOS transistor constituting the switch SW52 increases (to Vesd), and the switch SW52 is turned on. When the switch SW52 is turned on, the power supply node N12 and the gate of the output transistor 82 are electrically connected, a gate-drain voltage Vgd of the output transistor 82 increases, and the output transistor 82 is turned on.

Therefore, the output transistor 82 is driven at a voltage sufficient to allow the ESD current to flow.

Namely, the switch SW52 functions as a switching circuit configured to electrically connect the GND (reference potential line) and the gate of the output transistor 82 when the application of ESD to the GND (reference potential line) is detected.

Also, in this embodiment, the configuration in which either the switch SW51 or the switch SW52 is only provided is also possible. Then, for the output transistor to which the corresponding switch is not provided, a diode may be provided in parallel as in the conventional case.

With the above configuration, in the output driver of the semiconductor device 1C, the output transistors 81 and 82 constituting the driver circuit can be made use of as ESD protection elements by driving them at a voltage sufficient to allow the ESD current to flow. This makes it possible to reduce the size of the protection diode or remove the protection diode itself, contributing to the reduction in chip area.

Note that the above-described embodiments can be suitably applied not only to the SOI process, but also to a process in which a body diode is not formed due to the structure, such as a ground all around (GAA) structure. However, even when the embodiments are applied to a conventional bulk process, a large current can be made to flow from the channel in addition to the body diode, so that the stress voltage between the power supply line and the GND can be further alleviated.

Although the invention made by the inventor of this application has been specifically described on the basis of the embodiments, it goes without saying that the present invention is not limited to the embodiments described above and various modifications can be made within the range not departing from the gist thereof.

What is claimed is:

1. A semiconductor device comprising:
a protection transistor connected between a power supply line and a reference potential line;
a trigger circuit configured to detect an application of an electrostatic discharge to the power supply line and output a drive signal to a gate of the protection transistor; and
a switching circuit provided between the power supply line or the reference potential line and the gate of the protection transistor and configured to electrically connect the power supply line or the reference potential line and the gate of the protection transistor when the electrostatic discharge is applied to the reference potential line.

2. The semiconductor device according to claim 1,
wherein the trigger circuit includes:
a detection circuit configured to detect the electrostatic discharge; and
a drive circuit configured to drive the gate of the protection transistor based on a detection result of the detection circuit.

3. The semiconductor device according to claim 1,
wherein the switching circuit electrically connects the power supply line or the reference potential line and the gate of the protection transistor based on a potential of the power supply line or a potential of the reference potential line.

4. The semiconductor device according to claim 1,
wherein the trigger circuit is made up of a resistive element connected to the gate of the protection transistor and a capacitive element formed between a drain and the gate of the protection transistor.

5. The semiconductor device according to claim 1,
wherein a plurality of protection transistors each equivalent to the protection transistor are connected in series,
wherein the switching circuit is made up of a plurality of switching elements, and
wherein the plurality of switching elements electrically connect the power supply line or the reference potential line and the gate of one protection transistor of the plurality of protection transistors.

6. A semiconductor device comprising:
an output transistor connected between an output terminal and a power supply line; and
a switching circuit provided between the power supply line and a gate of the output transistor and configured to electrically connect the power supply line and the gate of the output transistor when an application of an electrostatic discharge to the output terminal is detected.

7. A semiconductor device comprising:
an output transistor connected between an output terminal and a reference potential line; and
a switching circuit provided between the reference potential line and a gate of the output transistor and configured to electrically connect the reference potential line and the gate of the output transistor when an application of an electrostatic discharge to the reference potential line is detected.
